(19) United States
(12) Patent Application Publication
(10) Pub. No.: US 2006/0082002 A1
(43) Pub. Date: Apr. 20, 2006

(54) Sheet for circuit substrates and sheet of a circuit substrate for displays

(75) Inventors: Takayuki Arai, Itabashi-ku (JP); Naofumi Izumi, Itabashi-ku (JP); Tomomi Tetsumoto, Saitama-shi (JP); Masahito Nakabayashi, Saitama-shi (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: LINTEC CORPORATION, Tokyo (JP)

(21) Appl. No.: 11/230,039

(22) Filed: Sep. 19, 2005

(30) Foreign Application Priority Data
Oct. 6, 2004 (JP) 2004-293978
Apr. 19, 2005 (JP) 2005-120750

(51) Int. Cl. H01L 23/28

(52) U.S. Cl. 257/787

(57) ABSTRACT

A sheet for circuit substrates for displays which comprises a polymer material of an energy ray hardening type for embedding circuit chips, wherein a storage modulus of an unhardened layer comprising the polymer material of an energy ray hardening type is 10³ Pa or greater and smaller than 10⁷ Pa at a temperature of embedding the circuit chips or at 25° C., and a storage modulus of a hardened layer obtained by hardening the unhardened layer is 10⁷ Pa or greater at 25° C.; and a sheet of circuit substrate for displays obtained by embedding circuit chips into the unhardened layer, followed by hardening the unhardened layer by irradiation with an energy ray. A sheet of a circuit substrate in which circuit chips for controlling pixels of displays and, in particular, flat panel displays are embedded into the sheet can be efficiently produced with excellent quality and productivity using the sheet for circuit substrates.

### BACKGROUND OF THE INVENTION

1. Field of the Invention

The present invention relates to a sheet for circuit substrates for displays and a sheet of a circuit substrate for displays. More particularly, the present invention relates to a sheet for circuit substrates for displays used for efficiently producing a sheet of a circuit substrate in which circuit chips for controlling pixels of displays and, in particular, flat panel displays are embedded into the sheet with excellent quality and productivity, and a sheet of a circuit substrate for displays comprising embedded circuit chips which is obtained by using the sheet for circuit substrates for displays.

2. Description of Related Art

In flat panel displays such as liquid crystal displays as the typical examples, an insulating film, a semiconductor film and the like are successively laminated on a glass substrate in accordance with the chemical vapor phase deposition (CVD) process, and minute electronic devices such as thin film transistors (TFT) are formed in the vicinity of each pixel constituting the screen of display in accordance with the same process as that conducted for producing a semiconductor integrated circuit. Switching each pixel on and off and the intensity exhibited by each pixel are controlled by the devices. In other words, minute devices such as TFT are formed on the substrate used for a display during the process of production. However, in accordance with the process described above, the process has many steps and is complicated, and it is inevitable that the cost increases. When the area of the display increases; the size of the apparatus for CVD for forming the films on the glass substrate increases, and the cost markedly increases.

To decrease the cost, a technology in which minutes chips of integrated circuits of silicon crystals are attached to a printing plate in a manner similar to attaching a printing ink, and the attached chips are transferred to prescribed positions on the substrate of the display and fixed there in accordance with the printing technology, is disclosed (for example, Patent Reference 1). In this technology, a polymer film is formed on the substrate of the display in advance, and the minutes chips of integrated circuits of silicon crystals are transferred to the polymer film in accordance with the printing technology and embedded into the polymer film in accordance with a process such as heat molding and heat pressing. However, in accordance with the process described above, strain and bubbles tend to be formed in the polymer film, and the process is not efficient since it takes time to heat the polymer film.

[Patent Reference 1] Japanese Patent Application Laid-Open No. 2003-248436

### BRIEF SUMMARY OF THE INVENTION

Under the above circumstances, the present invention has an object of providing a sheet for circuit substrates for displays used for efficiently producing a sheet of a circuit substrate in which circuit chips for controlling pixels of displays and, in particular, flat panel displays are embedded into the sheet with excellent quality and productivity, and a sheet of a circuit substrate for displays comprising embedded circuit chips which is obtained by using the sheet for circuit substrates for displays.

As the result of intensive studies by the present inventors to achieve the above object, it was found that a sheet of a circuit substrate for displays into which circuit chips were embedded could be efficiently produced with excellent quality and productivity by using for embedding the circuit chips a sheet for circuit substrates comprising a polymer material of the energy ray hardening type having each specific ranges of the storage moduli of the unhardened layer and the hardened layer, respectively. The present invention has been completed based on the knowledge.

The present invention provides:

(1) A sheet for circuit substrates which comprises a polymer material of an energy ray hardening type for embedding circuit chips and is used for displays, wherein a storage modulus of an unhardened layer comprising the polymer material of an energy ray hardening type is 10³ Pa or greater and smaller than 10⁷ Pa at a temperature of embedding the circuit chips, and a storage modulus of a hardened layer obtained by hardening the unhardened layer is 10⁷ Pa or greater at 25° C.;

(2) A sheet for circuit substrates described in (1), wherein the temperature of embedding the circuit chips is 150° C. or lower;

(3) A sheet for circuit substrates which comprises a polymer material of an energy ray hardening type for embedding circuit chips and is used for displays, wherein a storage modulus of an unhardened layer comprising the polymer material of an energy ray hardening type is 10³ to 10⁶ Pa at 25° C., and a storage modulus of a hardened layer obtained by hardening the unhardened layer is 10⁷ Pa or greater at 25° C.;

(4) A sheet for circuit substrates described in any one of (1) to (3), wherein the unhardened layer comprising the polymer material of an energy ray hardening type and the hardened layer obtained by hardening the unhardened layer both have a transmittance of light in a range of a wavelength of 400 to 800 nm of 80% or greater;

(5) A sheet for circuit substrates described in any one of (1) to (4), wherein the polymer material of an energy ray hardening type comprises a copolymer of a (meth)acrylic ester having a group hardenable with an energy ray at a side chain;

(6) A sheet for circuit substrates described in (5), wherein the group hardenable with an energy ray is an unsaturated group polymerizable with radicals, and the copolymer of a (meth)acrylic ester has a weight-average molecular weight of 100,000 or greater;

(7) A sheet for circuit substrates described in any one of (1) to (6), wherein the polymer material of an energy ray hardening type comprises a photoinitiator; and

(8) A sheet of a circuit substrate for displays obtained by embedding circuit chips into an unhardened layer comprising a polymer material of an energy ray hardening type in a sheet for circuit substrates described in any one of (1) to (7), followed by hardening the unhardened layer by irradiation with an energy ray.

In accordance with the present invention, a sheet for circuit substrates for displays used for efficiently producing a sheet of a circuit substrate in which circuit chips for controlling pixels of displays and, in particular, flat panel displays are embedded into the sheet with excellent quality and productivity, and a sheet of a circuit substrate for displays comprising embedded circuit chips which is obtained by using the sheet for circuit substrates, can be provided.

### BRIEF DESCRIPTION OF THE SEVERAL VIEWS OF THE DRAWINGS

FIG. 1 shows a schematic process diagram exhibiting an embodiment of the process for embedding circuit chips using the sheet for circuit substrates of the present invention.

FIG. 2 shows a diagram exhibiting an embedded circuit chip.

The numbers and characters in the figures have the meanings as listed in the following:
1: A support
2: A sheet for circuit substrates
3: Circuit chips
4: A glass plate
5: A sheet of a circuit substrate for displays
h: The height of a chip protruded from the sheet

### DETAILED DESCRIPTION OF THE INVENTION

The sheet for circuit substrates of the present invention is a sheet for displays comprising an unhardened layer comprising a polymer material of the energy ray hardening type for embedding circuit chips and includes two embodiments, i.e., sheet for circuit substrates I and sheet for circuit substrates II, which are shown in the following.

Sheet for circuit substrates I as the first embodiment is a sheet for circuit substrates which comprises a polymer material of the energy ray hardening type for embedding circuit chips. The storage modulus of an unhardened layer comprising the polymer material of the energy ray hardening type is 10³ Pa or greater and smaller than 10⁷ Pa at the temperature of embedding the circuit chips, and the storage modulus of a hardened layer obtained by hardening the unhardened layer is 10⁷ Pa or greater at 25° C.

In sheet for circuit substrate I, it is necessary that the polymer material of the energy ray hardening type for embedding circuit chips have a property such that the storage modulus of the unhardened layer be 10³ Pa or greater and smaller than 10⁷ Pa at the temperature of embedding the circuit chips. When the storage modulus is within the above range, the unhardened layer exhibits the excellent property of holding the shape, the excellent adhesion with a support and the excellent property for embedding the circuit chips. It is preferable that the storage modulus is in the range of 10⁴ to 5×10⁵ Pa. It is also necessary that the storage modulus of the hardened layer obtained by hardening the unhardened layer be 10⁷ Pa or greater at 25° C. When the storage modulus is 10⁷ Pa or greater, the property of maintaining the embedded circuit chips is excellent. There is no particular upper limit to the storage modulus. In general, the upper limit of the storage modulus is about 10¹² Pa. It is preferable that the storage modulus is in the range of 10⁸ to 10¹¹ Pa.

When the temperature of embedding the circuit chips is excessively high, there is the possibility that optical problems such as scatting of light arise due to generation of gases, and that the flatness of the circuit substrate is adversely affected. From these standpoint, it is preferable that the temperature of embedding the circuit chips is 0 to 150° C. and more preferably 5 to 100°.

Sheet for circuit substrates II as the second embodiment is a sheet for circuit substrates which comprises a polymer material of the energy ray hardening type for embedding circuit chips. The storage modulus of an unhardened layer comprising the polymer material of the energy ray hardening type is 10³ to 10⁶ Pa at 25° C., and the storage modulus of a hardened layer obtained by hardening the unhardened layer is 10⁷ Pa or greater at 25° C.

In sheet for circuit substrate II, it is necessary that the polymer material of the energy ray hardening type for embedding circuit chips have a property such that the storage modulus of the unhardened layer be 10³ to 10⁶ Pa at 25° C. When the storage modulus is within the above range, the unhardened layer exhibits the excellent property of holding the shape, the excellent adhesion with a support and the excellent property for embedding the circuit chips. It is preferable that the storage modulus is in the range of 10⁴ to 5×10⁵ Pa. It is also necessary that the storage modulus of the hardened layer obtained by hardening the unhardened layer is 10⁷ Pa or greater at 25° C. When the storage modulus is 10⁷ Pa or greater, the property of maintaining the embedded circuit chips is excellent. There is no particular upper limit to the storage modulus. In general, the upper limit of the storage modulus is about 10¹² Pa. It is preferable that the storage modulus is in the range of 10⁸ to 10¹¹ Pa.

The storage moduli of the unhardened layer comprising the polymer material of the energy ray hardening type and the hardened layer obtained by hardening the unhardened layer are measured in accordance with the method described later.

In the present invention, it is preferable from the standpoint of transmission of visible light that the unhardened layer comprising the polymer material of the energy ray hardening type and the hardened layer obtained by hardening the unhardened layer both have a transmittance of light in the range of the wavelength of 400 to 800 nm of 80% or greater at 25° C.

The transmittance of light in the range of the wavelength of 400 to 800 nm of the unhardened layer comprising the polymer material of the energy ray hardening type and the hardened layer obtained by hardening the unhardened layer is measured in accordance with the method described later.

In the present invention, the polymer material of the energy ray hardening type means a polymer material which can be crosslinked by irradiation with an electromagnetic wave or beams of charged particles having an energy quantum, i.e., ultraviolet light or electron beams.

Examples of the polymer material of the energy ray hardening type used in the present invention include (1) polymer materials comprising an adhesive acrylic polymer, at least one of a polymerizable oligomer of the energy ray hardening type and a polymerizable monomer of the energy ray hardening type and, where desired, a photoinitiator; and (2) polymer materials comprising an adhesive acrylic polymer obtained by introducing a functional group of the energy ray hardening type having a polymerizable unsaturated group into the side chain and, where desired, a photopolymerization initiator.

Preferable examples of the adhesive acrylic polymer in the above polymer material described above in (1) include copolymers of a (meth)acrylic ester having 1 to 20 carbon atoms in the ester portion with a monomer having a functional group having active hydrogen atom and other monomers which are used where desired, i.e., copolymers of (meth)acrylic esters. In the present invention, “(meth)acrylic ester” or “(meth)acrylate” means both acrylic ester and methacrylic ester or both acrylate and methacrylate, respectively.

Examples of the copolymers of a (meth)acrylic ester having 1 to 20 carbon atoms in the ester portion include methyl (meth)acrylate, ethyl (meth)acrylate, propyl (meth)acrylate, butyl (meth)acrylate, pentyl (meth)acrylate, hexyl (meth)acrylate, cyclohexyl (meth)acrylate, 2-ethylhexyl (meth)acrylate, isooctyl (meth)acrylate, decyl (meth)acrylate, dodecyl (meth)acrylate, myristyl (meth)acrylate, palmityl (meth)acrylate and stearyl (meth)acrylate. The copolymer of a (meth)acrylic ester may be used singly or in combination of two or more.

Examples of the monomer having a functional group having active hydrogen atom which is used where desired include hydroxyalkyl (meth)acrylates such as 2-hydroxyethyl (meth)acrylate, 2-hydroxypropyl (meth)acrylate, 3-hydroxypropyl (meth)acrylate, 2-hydroxybutyl (meth)acrylate, 3-hydroxybutyl (meth)acrylate and 4-hydroxybutyl (meth)acrylate; monoalkylaminoalkyl (meth)acrylates such as monomethylaminoethyl (meth)acrylate, monoethylaminoethyl (meth)acrylate, monomethylaminopropyl (meth)acrylate and monoethylaminopropyl (meth)acrylate; and ethylenically unsaturated carboxylic acids such as acrylic acid, methacrylic acid, crotonic acid, maleic acid, itaconic acid and citraconic acid. The above monomer may be used singly or in combination of two or more.

The copolymer of a (meth)acrylic ester comprises 5 to 100% by weight and preferably 50 to 95% by weight of the (meth)acrylic ester and 0 to 95% by weight and preferably 5 to 50% by weight of the monomer having a functional group having active hydrogen atom.

Examples of the other monomer which is used where desire include vinyl esters such as vinyl acetate and vinyl propionate; olefins such as ethylene, propylene and isobutylene; halogenated olefins such as vinyl chloride and vinylidene chloride; styrene-based monomers such as styrene and α-methylstyrene; diene-based monomers such as butadiene, isoprene and chloroprene; nitrile-based monomers such as acrylonitrile and methacrylonitrile; and acrylamides such as acrylamide, N-methylacrylamide and N,N-dimethylacrylamide. The other monomer may be used singly or in combination of two or more. The copolymer of a (meth)acrylic ester can comprise 0 to 30% by weight of the above monomer.

The form of the copolymer of a (meth)acrylic ester used as the adhesive acrylic polymer in the above polymer material is not particularly limited, and any of random copolymers, block copolymers and graft copolymers can be used. It is preferable that the molecular weight is 300,000 or greater as expressed by the weight-average molecular weight.

The weight-average molecular weight is the value obtained in accordance with the gel permeation chromatography (GPC) and expressed as the value of the corresponding polystyrene.

In the present invention, the copolymer of a (meth)acrylic ester may be used singly or in combination two or more.

Examples of the polymerizable oligomer of the energy ray hardening type include polyester acrylate-based oligomers, epoxy acrylate-based oligomers, urethane acrylate-based oligomers, polyether acrylate-based oligomers, polybutadiene acrylate-based oligomers and silicone acrylate-based oligomers. The polyester acrylate-based oligomer can be obtained, for example, by obtaining a polyester oligomer having hydroxyl groups at both ends by condensation of a polyfunctional carboxylic acid with a polyhydric alcohol, followed by esterification of the hydroxyl groups in the obtained oligomer with (meth)acrylic acid; or by obtaining an oligomer having hydroxyl groups at both ends by addition of an alkylene oxide to a polyfunctional carboxylic acid, followed by esterification of the hydroxyl groups of the obtained oligomer with (meth)acrylic acid. The epoxy acrylate-based oligomer can be obtained, for example, by esterification of oxirane rings in an epoxy resin of a bisphenol type or a novolak type having a relatively low molecular weight by the reaction with (meth)acrylic acid. Epoxy acrylate oligomers modified with carboxyl group which are obtained by partially modifying the above epoxy acrylate oligomer with a dibasic carboxylic acid anhydride can also be used. The urethane acrylate-based oligomer can be obtained, for example, by the reaction of a polyether polyol or a polyester polyol with a polyisocyanate to obtain a polyurethane oligomer, followed by esterification of the obtained polyurethane oligomer with (meth)acrylic acid. The polyol acrylate-based oligomer can be obtained, for example, by esterification of hydroxyl groups in a polyether polyol with (meth)acrylic acid.

It is preferable that the weight-average molecular weight of the above polymerizable oligomer is selected in the range of 500 to 100,000, more preferably in the range of 1,000 to 70,000 and most preferably in the range of 3,000 to 40,000 as obtained in accordance with the gel permeation chromatography (GPC) and expressed as the value of the corresponding polymethyl methacrylate.

The polymerizable oligomer may be used singly or in combination of two or more.

Examples of the polymerizable monomer of the energy ray hardening type include monofunctional esters of (meth)acrylic acid such as cyclohexyl (meth)acrylate, 2-ethylhexyl (meth)acrylate, lauryl (meth)acrylate, stearyl (meth)acrylate and isobornyl (meth)acrylate, 1,4-butanediol di(meth)acrylate, 1,6-hexanediol di(meth)acrylate, neopentyl glycol di(meth)acrylate, polyethylene glycol di(meth)acrylate, neopentyl glycol adipate di(meth)acrylate, neopentyl glycol hydroxypivalate di(meth)acrylate, dicyclopentanyl di(meth)acrylate, caprolactone-modified dicyclopentenyl di(meth)acrylate, ethylene oxide-modified phosphate di(meth)acrylate, allyl-modified cyclohexyl di(meth)acrylate, isocyanurate di(meth)acrylate, di-methyloltricyclodecane di(meth)acrylate, trimethylolpropane tri(meth)acrylate, dipentaerythritol tri(meth)acrylate, propionic acid-modified dipentaerythritol tri(meth)acrylate, pentaerythritol tri(meth)acrylate, propylene oxide-modified trimethylolpropane tri(meth)acrylate, tris(acryloxyethyl) isocyanurate, propionic acid-modified dipentaerythritol penta(meth)acrylate, dipentaerythritol hexa(meth)acrylate and caprolactone-modified dipentaerythritol hexa(meth) acrylate. The polymerizable monomer of the energy ray hardening type may be used singly or in combination of two or more.

The amounts of the polymerizable oligomer and the polymerizable monomer are selected in a manner such that the polymer material has the properties described above after being hardened by application of an energy ray. In general, the polymerizable oligomer and the polymerizable monomers are each used in an amount of 3 to 300 parts by weight per 100 parts by weight of the solid components in the copolymer of a (meth)acrylic ester.

As the energy ray, in general, ultraviolet light or electron beams are used for the irradiation. When ultraviolet light is used for the irradiation, a photoinitiator can be used. Examples of the photoinitiator include benzoin, benzoin methyl ether, benzoin ethyl ether, benzoin isopropyl ether, benzoin n-butyl ether, benzoin isobutyl ether, acetophenone, dimethylacetophenone, 2,2-dimethoxy-2-phenyl-acetophenone, 2,2-diethoxy-2-phenylacetophenone, 2-hydroxy-2-methyl-1-phenylpropane-1-one, 1-hydroxycyclohexyl phenyl ketone, 2-methyl-1-[4-(methylthio)phenyl]-2-morpholinopropane-1-one, 4-(2-hydroxyethoxy)phenyl 2-(hydroxy-2-propyl) ketone, benzophenone, p-phenylbenzophenone, 4,4′-diethylaminobenzophenone, dichloro-benzophenone, 2-methylanthraquinone, 2-ethylanthraquinone, 2-tertiary-butylanthraquinone, 2-aminoanthraquinone, 2-methylthioxanthone, 2-ethylthioxanthone, 2-chlorothioxanthone, 2,4-dimethylthioxanthone, 2,4-diethylthioxanthone, benzyl dimethyl ketal, acetophenone dimethyl ketal, p-dimethylaminobenzoic acid esters and oligo(2-hydroxy-2-methyl-1-[4-(1-propenyl)phenyl]propanone). The photoinitiator may be used singly or in combination of two or more.

The amount of the photoinitiator is, in general, 0.1 to 10 parts by weight per 100 parts by weight of the solid components in the polymer material of the energy ray hardening type.

Examples of the adhesive acrylic polymer of the energy ray hardening type having an unsaturated group polymerizable with radicals at the side chain in the polymer material described above in (2) include polymers prepared by introducing an active point such as —COOH, —NCO, epoxy group, —OH and —NH₂ into the polymer chain of the adhesive acrylic polymer described above for the polymer material in (1), followed by reacting a compound having a unsaturated group polymerizable with radicals with the introduced active point to introduce a functional group of the energy ray hardening type having an unsaturated group polymerizable with radicals into the side chain of the adhesive acrylic polymer.

The active point described above can be introduced into the adhesive acrylic polymer by preparing the adhesive acrylic polymer in the presence of a monomer or an oligomer having a functional group such as —COOH, —NCO, epoxy group, —OH and —NH₂ and an unsaturated group polymerizable with radicals.

Specifically, when the acrylic polymer described for the polymer material of (1) is produced, (meth)acrylic acid can be used for introducing —COOH group, 2-(meth)acryloyloxyethyl isocyanate can be used for introducing —NCO group, glycidyl (meth)acrylate can be used for introducing epoxy group, 2-hydroxyethyl (meth)acrylate and 1,6-hexanediol mono(meth)acrylate can be used for introducing —OH group, and N-methyl(meth)acrylamide can be used for introducing —NH₂ group.

As the compound having an unsaturated group polymerizable with radicals which is used for the reaction with the active point, a compound can be suitably selected, for example, from 2-(meth)acryloyloxyethyl isocyanate, glycidyl (meth)acrylate, pentaerythritol mono(meth)acrylate, dipentaerythritol mono(meth)acrylate and trimethylolpropane mono(meth)acrylate in accordance with the type of the active point.

The adhesive acrylic polymer in which a functional group of the energy ray hardening type having an unsaturated group polymerizable with radicals is introduced into the side chain via the active point, i.e., the copolymer of a (meth)acrylic ester, can be obtained as described above.

It is preferable that the copolymer of a (meth)acrylic ester having a functional group of the energy ray hardening type has a weight-average molecular weight of 100,000 or greater and more preferably 300,000 or greater. The weight-average molecular weight is the value obtained in accordance with the gel permeation chromatography (GPC) and expressed as the value of the corresponding polystyrene.

As the photoinitiator used where desired, the photoinitiators described as the examples in the description for the polymer material of (1) can be used.

To the polymer materials of the energy ray hardening type of (1) and (2), where desired, crosslinking agents, tackifiers, antioxidants, ultraviolet light absorbents, photostabilizers, softening agents and fillers can be added as long as the effects of the present invention are not adversely affected.

Examples of the crosslinking agent include polyisocyanate compounds, epoxy resins, melamine resins, urea resins, dialdehydes, methylol polymers, aziridine-based compounds, metal chelate compounds, metal alkoxides and metal salts. Polyisocyanates are preferable among these agents. The crosslinking agent can be used in an amount of 0 to 30 parts by weight per 100 parts by weight of the solid components in the copolymer of a (meth)acrylic ester described above.

Examples of the polyisocyanate compound include aromatic polyisocyanates such as tolylene diisocyanate, diphenylmethane diisocyanate and xylylene diisocyanate; aliphatic polyisocyanates such as hexamethylene diisocyanate; alicyclic polyisocyanates such as isophorone diisocyanate and hydrogenated diphenylmethane diisocyanate; biuret compounds and isocyanurates of the above isocyanates; and adducts of the above isocyanates which are reaction products with low molecular weight compounds having active hydrogen such as ethylene glycol, propylene glycol, neopentyl glycol, trimethylolpropane and caster oil. The crosslinking agent may be used singly or in combination of two or more.

To control the modulus of the polymer materials of (1) and (2), the copolymer of a (meth)acrylic ester of the energy ray hardening type having an unsaturated group polymerizable with radicals at the side chain described for the polymer material of (2) can be added to the polymer material of the energy ray hardening type of (1). Similarly, the adhesive acrylic polymer, the oligomer of the energy ray hardening type or the polymerizable monomer of the energy ray hardening type described for the polymer material of (1) can be added to the polymer material of the energy ray hardening type of (2).

The sheet for circuit substrates of the present invention may comprise a support on the face opposite to the face for embedding circuit chips.

The above support is not particularly limited, and a support can be suitably selected as desired from transparent supports conventionally used as the support for displays. Examples of the support include glass plates and plastic supports having a plate shape or a film shape. Examples of the glass plate include plates of soda lime glass, glass containing barium and strontium, aluminosilicate glass, lead glass, borosilicate glass, barium borosilicate glass and quartz. Examples of the plastic support having a plate shape or a film shape include plates and films of polycarbonate resins, acrylic resins, polyethylene terephthalate resins, polyether sulfide resins, polysulfone resins and polycycloolefin resins. The thickness of the support is suitably selected in accordance with the application. The thickness is, in general, about 20 μm to 5 mm and preferably 50 μm to 2 mm.

The process for producing the sheet for circuit substrates is not particularly limited. An unhardened layer may be formed by directly applying a coating fluid comprising the above polymer material of the energy ray hardening type in a suitable concentration to a support in an amount such that the formed coating film has the prescribed thickness after being dried in accordance with a process such as the knife coating process, the roll coating process, the bar coating process, the blade coating process, the die coating process and the gravure coating process, followed by drying the formed coating layer.

The unhardened layer may be formed on a release layer of a release sheet by coating the above coating fluid in accordance with the above process, followed by drying the formed coating layer, and the formed unhardened layer may be transferred to the support. An unhardened sheet having a release sheet on both faces may be prepared using the above coating fluid and a release sheet. In this case, the order of release can be suitably set by setting the releasing strength of the release sheets on the two faces at values different from each other. A plurality of unhardened layer may be laminated to obtain the desired thickness.

In the sheet for circuit substrates, where desired, a release sheet may be disposed on the unhardened layer, and the release sheet may be removed before the use. When the sheet for circuit substrates has release sheets on both faces, the release sheet remaining after removal of one release sheet may be used as the support.

The thickness of the unhardened layer is, in general, about 50 to 1,000 μm and preferably 80 to 500 μm although the thickness is different depending on the condition of the use.

The release sheet is not particularly limited. Examples of the release sheet include release sheets having a layer of a release agent formed by coating a polyolefin film such as a polyethylene film and a polypropylene film or a polyester film such as a polyethylene terephthalate film with a release agent such as a silicone resin. The thickness of the release sheet is, in general, about 20 to 150 μm.

The sheet of a circuit substrate for displays of the present invention can be prepared by embedding circuit chips into the unhardened layer comprising the polymer material of the energy ray hardening type in the sheet for circuit substrates obtained as described above, followed by hardening the unhardened layer having the embedded circuit chips by irradiating with an energy ray.

The process will be described more specifically. Circuit chips for embedding are placed on a glass plate or the like, and the sheet for circuit substrates is placed on the circuit chips in a manner such that the unhardened layer is brought into contact with the circuit chips. Under a load of about 0.05 to 2.0 MPa, the circuit chips are embedded into the unhardened layer at a temperature of 0 to 150° C. or lower and preferably 5 to 100° C. or lower. After the unhardened layer is hardened by irradiation with an energy ray, the hardened layer is separated from the glass plate, and the sheet of a circuit substrate for displays of the present invention can be obtained. When the circuit chips are embedded under heating, the irradiation with an energy ray may be conducted while the unhardened layer is heated or after the unhardened layer is cooled to the room temperature.

As the energy ray, in general, ultraviolet light or electron beams are used. Ultraviolet light can be obtained from a high voltage mercury lamp, a fusion H lamp or a xenon lamp. Electron beams are obtained from an electron beam accelerator. Among these energy rays, ultraviolet light is preferable. The amount of the energy ray used for the irradiation is suitably selected so that the storage modulus of the hardened layer is within the above range. For example, when ultraviolet light is used, an amount of light of 100 to 500 mJ/cm² is preferable. When electron beams are used, an amount of beams of 10 to 1,000 krad is preferable.

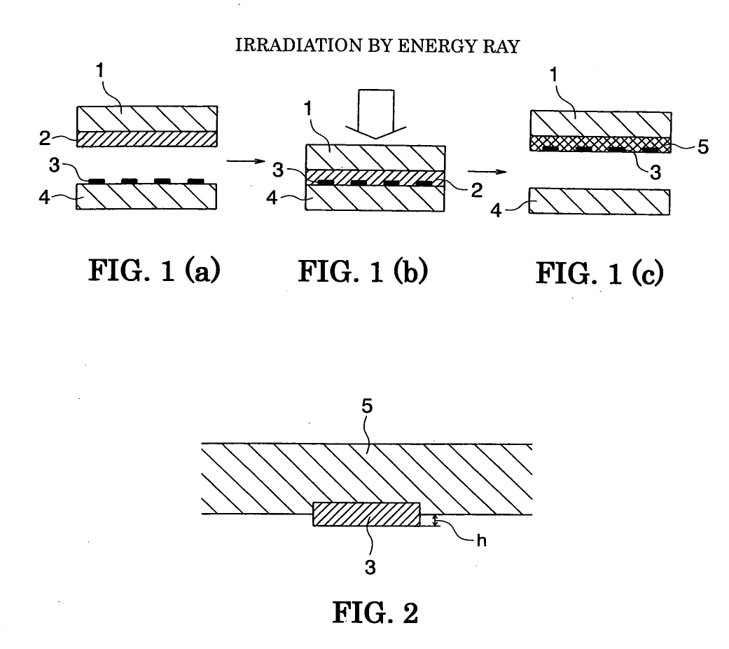

FIG. 1 shows a schematic process diagram exhibiting an embodiment of the process for embedding circuit chips using the sheet for circuit substrates of the present invention.

The sheet for circuit substrates 2 of the present invention comprising the unhardened polymer material of the energy ray hardening type is placed on a support 1. Separately, circuit chips 3 are placed on a glass plate 4 [FIG. 1 (a)]. Then, the sheet for circuit substrates 2 is placed on the circuit chips 3 so that the sheet for circuit substrates 2 is brought into contact with the circuit chips 3. The chips are embedded into the sheet under a load, and the sheet is hardened by irradiation with an energy ray [FIG. 1 (b)]. The sheet for circuit substrates 2 in the unhardened condition is converted into a hardened layer due to this operation. The circuit chips 3 are embedded into and fixed to the hardened layer, and the sheet of a circuit substrate for displays 5 of the present invention is easily separated from the glass plate 4 [FIG. 1 (c)].

In accordance with the technology of the present invention, since the circuit chips are embedded into the sheet, not by heating a polymer film, but by using the polymer material of the energy ray hardening type, which is then hardened to fix the circuit chips, problems due to the use of the polymer film are prevented, the operation is efficient due to the decreased time of the operation, and the circuit chips are embedded excellently.

### EXAMPLES

The present invention will be described more specifically with reference to examples in the following. However, the present invention is not limited to the examples.

The properties of a polymer material of the energy ray hardening type obtained in Examples were obtained in accordance with the methods described in the following.

(1) Storage Modulus of an Unhardened Layer

The releasing face of a release sheet was coated with a coating fluid prepared in an Example. The formed coating layer was dried at 90° C. for 1 minute, and an unhardened layer having a thickness of 50 μm was formed. By lamination of layers prepared in this manner, a sample having a thickness of 3 mm and a diameter of 7.9 mm was prepared. The storage modulus of the unhardened layer was measured using an apparatus for measuring viscoelasticity [manufactured by RHEOMETRICS Company; the name of the apparatus: “DYNAMIC ANALYZER RDAII”] at 1 Hz at 5° C., 25° C., 90° C. or 140° C., respectively.

(2) Storage Modulus of a Hardened Layer

The releasing face of a release sheet was coated with a coating fluid prepared in an Example. The formed coating layer was dried at 90° C. for 1 minute, and an unhardened layer having a thickness of 47 μm was formed. By lamination of layers prepared in this manner, an unhardened layer having a thickness of 188 μm was prepared. After the prepared unhardened layer was hardened by irradiation with ultraviolet light from a light source of a metal halide lamp under a condition of an illuminance of 310 mW/cm² and an amount of light of 300 mJ/cm², the hardened layer was cut into a sample having a length of 30 mm and a width of 2 mm, and the storage modulus after being hardened was measured using an apparatus for measuring viscoelasticity [manufactured by ORIENTEC Co., LTD.; the name of the apparatus: “RHEOVIBRON DDV-II-EP”] at 3.5 Hz at 25° C.

(3) Transmittance of an Unhardened Layer

Using a sheet which was composed of an unhardened layer having a thickness of 188 μm and two release films disposed on both faces, one of the release films was removed. The exposed unhardened layer was laminated to a soda lime glass plate [manufactured by Nippon Sheet Glass Co., Ltd.; soda lime glass; the thickness: 1.1 mm], and the other release film was then removed. The transmittance of the obtained sheet (the sample for the measurement) in the unhardened condition was measured at 25° C. using a spectrophotometer [manufactured by SHIMADZU CORPORATION; a UV-VIS-NIR scanning spectrometer; UV-3101P] at a wavelength of the measurement of 400 to 800 nm, and the minimum value among the values obtained by the measurement was used as the transmittance.

(4) Transmittance of a Hardened Layer

The same sample for the measurement as that used in the measurement of the transmittance of the unhardened layer in (3) described above was hardened by irradiation with ultraviolet light from the light source of a metal halide lamp under the condition of an illuminance of 310 mW/cm² and an amount of light of 300 mJ/cm². Then, the transmittance of the hardened sheet was measured at 25° C. using a spectrophotometer [manufactured by SHIMADZU CORPORATION; a UV-VIS-NIR scanning spectrometer; UV-3101P] at a wavelength of the measurement of 400 to 800 nm, and the minimum value among the values obtained by the measurement was used as the transmittance.

(5) Property for Embedding

A silicon chip (having a length of 500 μm, a width of 500 μm and a thickness of 50 μm) was placed on a soda lime glass plate, and a sheet for circuit substrates obtained in one of Examples 1 to 5 was laminated to the glass plate having the silicon chips under a pressure of 0.2 MPa after the release sheet of the lightly releasing type in the sheet for circuit substrates was removed. During the lamination, the glass plate was placed on a table which was placed on a plate the temperature of which can be controlled and kept at 5° C., 25° C., 90° C. or 140° C., respectively. After the pressure was kept at the above value for 5 minutes, the pressure was released to the ordinary pressure. Then, the hardening was conducted by irradiation with ultraviolet light from the light source of a metal halide lamp under the condition of an illuminance of 310 mW/cm² and an amount of light of 300 mJ/cm² and a sheet of circuit substrate sheet for displays was obtained. The obtained sheet of circuit substrate for displays was separated from the glass plate and, as shown in FIG. 2, the condition of the embedded silicon chip was observed using a confocal microscope [manufactured by Lasertec Corporation; the trade name: “HD100D”]. The height of the chip protruded from the face of the hardened layer h was measured, and the property for embedding was evaluated in accordance with the following criteria:
good: the height of the chip protruded from the face of the hardened layer was smaller than 10 μm
poor: the height of the chip protruded from the face of the hardened layer was 10 μm or greater

FIG. 2 shows a diagram exhibiting an embedded circuit chip. In FIG. 2, h means the height of the chip protruded from the face of the hardened layer.

### Example 1

To a solution of a copolymer of an acrylic ester (the concentration of the solid components: 35% by weight) obtained by the reaction of 80 parts by weight of butyl acrylate and 20 parts by weight of acrylic acid in a mixed solvent of ethyl acetate and methyl ethyl ketone (the ratio of the amounts by weight: 50:50), 2-methacryloyloxyethyl isocyanate was added in an amount of 30 equivalents per 100 equivalents of acrylic acid in the copolymer. The reaction was allowed to proceed at 40° C. for 48 hours under the atmosphere of nitrogen, and a copolymer of the energy ray hardening type which had a group hardenable with an energy ray at the side chain and had a weight-average molecular weight of 850,000 was obtained. Into the obtained solution of the copolymer of the energy ray hardening type, 4.0 parts by weight of oligo{2-hydroxy-2-methyl-1-[4-(1-propenyl)phenyl]propanone} [manufactured by LAMBERTI SPA Company; “ESACURE KIP 150”] as the photoinitiator, 100 parts by weight of a composition comprising a polyfunctional monomer of the energy ray hardening type and an oligomer of the energy ray hardening type [manufactured by DAINICHI SEIKA COLOR & CHEMICALS MFG. Co., Ltd.; SEIKA BEAM “14-29B(NPI)”] and 1.2 parts by weight of a crosslinking agent comprising a polyisocyanate compound [manufactured by TOYO INK MFG. Co., Ltd.; “ORIBAIN BHS-8515”] per 100 parts by weight of the solid components in the solution of the copolymer of the energy ray hardening type were dissolved. The concentration of the solid components was adjusted at 40% by weight, and a coating fluid comprising a polymer material of the energy ray hardening type was prepared.

The prepared coating fluid was applied to the face treated for releasing of release sheet of the heavily releasing type [manufactured by LINTEC Corporation; the trade name: “SP-PET3811”] on the face treated for releasing by a knife coater and dried by heating at 90° C. for 1 minute, and an unhardened layer comprising the polymer material of the energy ray hardening type having a thickness of 47 μm was formed. In accordance with the same procedure, an unhardened layer having a thickness of 47 μm was formed on the face treated for releasing of a release sheet of the lightly releasing type [manufactured by LINTEC Corporation; the trade name: “SP-PET3801”], which had a layer of a silicone-based releasing agent on one face of a polyethylene terephthalate film. Three sheets having a release sheet of the lightly releasing type were prepared in this manner. The unhardened layer in one of the prepared sheets having a release sheet of the lightly releasing type was laminated to the unhardened layer formed on the release sheet of the heavily releasing type, and the release sheet of the lightly releasing type was removed. This procedure was repeated, and a sheet for circuit substrates having an unhardened layer comprising the polymer material of the energy ray hardening type and having a thickness of 188 μm, which had the release sheet of the heavily releasing type on one face and the release sheet of the lightly releasing type on the other face, was obtained.

The properties of the obtained sheet for circuit substrates are shown in Table 1.

### Example 2

Solution of a copolymer of an acrylic ester A (the concentration of the solid components: 35% by weight) was prepared by the reaction of 80 parts by weight of butyl acrylate and 20 parts by weight of acrylic acid in a mixed solvent of ethyl acetate and methyl ethyl ketone (the ratio of the amounts by weight: 50:50). Separately, Solution of a copolymer of an acrylic ester B (the concentration of the solid components: 35% by weight) was prepared by the reaction of 80 parts by weight of butyl acrylate and 20 parts by weight of acrylic acid in a mixed solvent of ethyl acetate and methyl ethyl ketone (the ratio of the amounts by weight: 50:50). To Solution of a copolymer of an acrylic ester B, 2-methacryloyloxyethyl isocyanate was added in an amount of 30 equivalents per 100 equivalents of acrylic acid in the copolymer. The reaction was allowed to proceed at 40° C. for 48 hours under the atmosphere of nitrogen, and a copolymer of the energy ray hardening type which had a group hardenable with an energy ray at the side chain and had a weight-average molecular weight of 850,000 was prepared. Solution of a copolymer of an acrylic ester A and the copolymer of the energy ray hardening type prepared above were mixed in amounts such that the ratio of the amount by weight of the solid components in solution of a copolymer of an acrylic ester A to the amount by weight of the copolymer of the energy ray hardening type was 10:90. Into the obtained mixed solution, 1-hydroxycyclohexyl phenyl ketone [manufactured by CIBA SPECIALTY CHEMICALS Company; “IRGACURE 184”] as the photoinitiator was dissolved in an amount of 3.0 parts by weight per 100 parts by weight of the solid components in the obtained mixed solution. The concentration of the solid components was adjusted at 33% by weight, and a coating fluid comprising a polymer material of the energy ray hardening type was prepared.

Using the prepared coating fluid, a sheet for circuit substrates was prepared in accordance with the same procedures as those conducted in Example 1.

The properties of the sheet for circuit substrates are shown in Table 1.

### Example 3

To a solution of a copolymer of an acrylic ester (the concentration of the solid components: 35% by weight) obtained by the reaction of 80 parts by weight of butyl acrylate and 20 parts by weight of acrylic acid in a mixed solvent of ethyl acetate and methyl ethyl ketone (the ratio of the amounts by weight: 50:50), 2-methacryloyloxyethyl isocyanate was added in an amount of 30 equivalents per 100 equivalents of acrylic acid in the copolymer. The reaction was allowed to proceed at 40° C. for 48 hours under the atmosphere of nitrogen, and a copolymer of the energy ray hardening type which had a group hardenable with an energy ray at the side chain and had a weight-average molecular weight of 850,000 was prepared. Into the obtained solution of the copolymer of the energy ray hardening type, 1-hydroxycyclohexyl phenyl ketone [manufactured by CIBA SPECIALTY—CHEMICALS Company; “IRGACURE 184”] as the photoinitiator was dissolved in an amount of 3.8 parts by weight per 100 parts by weight of the solid components in the solution of the copolymer of the energy ray hardening type. The concentration of the solid components was adjusted at 33% by weight, and a coating fluid comprising a polymer material of the energy ray hardening type was prepared.

Using the prepared coating fluid, a sheet for circuit substrates was prepared in accordance with the same procedures as those conducted in Example 1.

The properties of the sheet for circuit substrates are shown in Table 1.

### Example 4

To a solution of a copolymer of an acrylic ester (the concentration of the solid components: 40% by weight) obtained by the reaction of 80 parts by weight of 2-ethylhexyl acrylate and 20 parts by weight of 2-hydroxyethyl acrylate in a solvent of ethyl acetate, 2-methacryloyloxy-ethyl isocyanate was added in an amount of 78.5 equivalents per 100 equivalents of 2-hydroxyethyl acrylate in the copolymer. After 0.025 parts by weight of dibutyltin dilaurate was added as the catalyst, the reaction was allowed to proceed at 40° C. for 48 hours under the atmosphere of nitrogen, and a copolymer of the energy ray hardening type which had a group hardenable with an energy ray at the side chain and had a weight-average molecular weight of 850,000 was obtained.

Into the obtained solution of the copolymer of the energy ray hardening type, 1-hydroxycyclohexyl phenyl ketone [manufactured by CIBA SPECIALTY CHEMICALS Company; “IRGACURE 184”] as the photoinitiator was dissolved in an amount of 3.8 parts by weight per 100 parts by weight of the solid components in the solution of the copolymer of the energy ray hardening type. The concentration of the solid components was adjusted at 33% by weight, and a coating fluid comprising a polymer material of the energy ray hardening type was prepared.

Using the prepared coating fluid, a sheet for circuit substrates was prepared in accordance with the same procedures as those conducted in Example 1.

The properties of the sheet for circuit substrates are shown in Table 1.

### Example 5

To a solution of a copolymer of an acrylic ester (the concentration of the solid components: 35% by weight) obtained by the reaction of 80 parts by weight of butyl acrylate and 20 parts by weight of acrylic acid in a mixed solvent of ethyl acetate and methyl ethyl ketone (the ratio of the amounts by weight: 50:50), 50 parts by weight of a composition comprising a polyfunctional monomer of the energy ray hardening type and an oligomer of the energy ray hardening type [manufactured by DAINICHI SEIKA COLOR & CHEMICALS MFG. Co., Ltd.; SEIKA BEAM “14-29B(NPI)”], 5 parts by weight of a photoinitiator [manufactured by LAMBERTI SPA Company; “ESACURE KIP 150”], and 1.2 parts by weight of a crosslinking agent comprising a polyisocyanate compound [manufactured by TOYO INK MFG. Co., Ltd.; “ORIBAIN BHS-8515”] per 100 parts by weight of the solid components in the solution of a copolymer of an acrylic ester were dissolved. The concentration of the solid components was adjusted at 40% by weight, and a coating fluid comprising a polymer material of the energy ray hardening type was prepared. Using the prepared coating fluid, a sheet for circuit substrates was prepared in accordance with the same procedures as those conducted in Example 1. The properties of the sheet for circuit substrates are shown in Table 1.

### Example 6

To a solution of a copolymer of an acrylic ester having a weight-average molecular weight of 850,000 (the concentration of the solid components: 35% by weight) obtained by the reaction of 80 parts by weight of butyl acrylate and 20 parts by weight of acrylic acid in a mixed solvent of ethyl acetate and methyl ethyl ketone (the ratio of the amounts by weight: 50:50), 120 parts by weight of di-methyloltricyclodecane diacrylate [manufactured by KYOEISHA CHEMICAL CO., LTD; “LIGHT ACRYLATE DCP-A”], 6.6 parts by weight of 1-hydroxycyclohexylphenylketone as a photoinitiator [manufactured by CIBA SPECIALTY CHEMICALS Company; IRGACURE 184] and 1.5 parts by weight of a crosslinking agent comprising polyisocyanate compound [manufactured by TOYO INK MFG. Co., Ltd.; “ORIBAIN BHS-8515”] per 100 parts by weight of the solid components in the solution of afore-said copolymer of the acrylic ester were dissolved. The concentration of the solid components in the solution was finally adjusted at 45% by weight by adding methyletylketone, and a coating fluid comprising a polymer material of the energy ray hardening type was prepared. Using the prepared coating fluid, a sheet for circuit substrates was prepared in accordance with the same procedures as those conducted in Example 1.

### Example 7

To a solution of a copolymer of an acrylic ester (the concentration of the solid components: 35% by weight) obtained by the reaction of 60 parts by weight of butyl acrylate, 20 parts by weight of methyl methacrylate and 20 parts by weight of acrylic acid in a mixed solvent of ethyl acetate and methyl ethyl ketone (the ratio of the amounts by weight: 50:50), 2-methacryloyloxy isocyanate was added in an amount of 30 equivalents per 100 equivalents of acrylic acid in the copolymer. The reaction was allowed to proceed at 40° C. for 48 hours under the atmosphere of nitrogen, and a copolymer of the energy ray hardening type which had a group hardenable with an energy ray at the side chain and had a weight-average molecular weight of 750,000 was prepared. Into the obtained solution of the copolymer of the energy ray hardening type, 1-hydroxycyclohexyl phenyl ketone [manufactured by CIBA SPECIALTY CHEMICALS Company; “IRGACURE 184”] as the photoinitiator was dissolved in an amount of 3.8 parts by weight per 100 parts by weight of the solid components in the solution of the copolymer of the energy ray hardening type. The concentration of the solid components was adjusted at 33% by weight, and a coating fluid comprising a polymer material of the energy ray hardening type was prepared.

Using the prepared coating fluid, a sheet for circuit substrates was prepared in accordance with the same procedures as those conducted in Example 1.

TABLE 1

| | Example | | | | | | |
|---|---|---|---|---|---|---|---|
| | 1 | 2 | 3 | 4 | 5 | 6 | 7 |
| Storage modulus (Pa) | | | | | | | |
| before hardening | | | | | | | |
| temperature of embedding | | | | | | | |
| 5° C. | 4.82 × 10⁵ | 6.11 × 10⁵ | 5.64 × 10⁶ | 3.63 × 10⁵ | 3.70 × 10⁵ | 7.98 × 10⁴ | 7.85 × 10⁶ |
| 25° C. | 7.42 × 10⁴ | 8.42 × 10⁴ | 1.22 × 10⁵ | 6.14 × 10⁴ | 6.20 × 10⁴ | 1.72 × 10⁴ | 4.95 × 10⁵ |
| 90° C. | 3.82 × 10⁴ | 4.93 × 10⁴ | 7.01 × 10⁴ | 2.18 × 10⁴ | 3.80 × 10⁴ | 9.85 × 10³ | 7.55 × 10⁴ |
| 140° C. | 1.89 × 10⁴ | 2.98 × 10⁴ | 3.30 × 10⁴ | 9.88 × 10³ | 1.74 × 10⁴ | 8.90 × 10³ | 3.65 × 10⁴ |
| after hardening (25° C.) | 1.62 × 10⁹ | 1.12 × 10⁹ | 8.10 × 10⁸ | 3.20 × 10¹⁰ | 1.81 × 10⁹ | 1.81 × 10¹⁰ | 8.90 × 10⁸ |
| Transmittance of light of 400 to | | | | | | | |
| 800 nm (25° C.) | | | | | | | |
| before hardening | 89 | 89 | 90 | 91 | 90 | 89 | 90 |
| after hardening | 92 | 91 | 91 | 92 | 92 | 90 | 91 |
| Property for embedding (see Note) | | | | | | | |
| temperature of embedding | | | | | | | |
| 5° C. | good(6) | good(6) | good(9) | good(5) | good(5) | good(3) | good(9) |
| 25° C. | good(3) | good(3) | good(5) | good(2) | good(3) | good(1) | good(7) |
| 90° C. | good(1) | good(2) | good(3) | good(1) | good(1) | good(<1) | good(3) |
| 140° C. | good(<1) | good(<1) | good(<1) | good(<1) | good(<1) | good(<1) | good(<1) |

Note:
Numbers in parentheses show height in μm of chips protruded from the face of hardened layer.

What is claimed is:

1. A sheet for circuit substrates which comprises a macromolecular material of an energy ray hardening type for embedding circuit chips and is used for displays, wherein a storage modulus of an unhardened layer comprising the polymer material of an energy ray hardening type is 10³ Pa or greater and smaller than 10⁷ Pa at a temperature of embedding the circuit chips, and a storage modulus of a hardened layer obtained by hardening the unhardened layer is 10⁷ Pa or greater at 25° C.

2. A sheet for circuit substrates according to claim 1, wherein the temperature of embedding the circuit chips is 150° C. or lower.

3. A sheet for circuit substrates which comprises a polymer material of an energy ray hardening type for embedding circuit chips and is used for displays, wherein a storage modulus of an unhardened layer comprising the polymer material of an energy ray hardening type is 10³ to 10⁶ Pa at 25° C., and a storage modulus of a hardened layer obtained by hardening the unhardened layer is 10⁷ Pa or greater at 25° C.

4. A sheet for circuit substrates according to claim 1, wherein the unhardened layer comprising the polymer material of an energy ray hardening type and the hardened layer obtained by hardening the unhardened layer both have a transmittance of light in a range of a wavelength of 400 to 800 nm of 80% or greater.

5. A sheet for circuit substrates according to claim 3, wherein the unhardened layer comprising the polymer material of an energy ray hardening type and the hardened layer obtained by hardening the unhardened layer both have a transmittance of light in a range of a wavelength of 400 to 800 nm of 80% or greater.

6. A sheet for circuit substrates according to claim 1, wherein the polymer material of an energy ray hardening type comprises a copolymer of a (meth)acrylic ester having a group hardenable with an energy ray at a side chain.

7. A sheet for circuit substrates according to claim 3, wherein the polymer material of an energy ray hardening type comprises a copolymer of a (meth)acrylic ester having a group hardenable with an energy ray at a side chain.

8. A sheet for circuit substrates according to claim 6, wherein the group hardenable with an energy ray is an unsaturated group polymerizable with radicals, and the copolymer of a (meth)acrylic ester has a weight-average molecular weight of 100,000 or greater.

9. A sheet for circuit substrates according to claim 7, wherein the group hardenable with an energy ray is an unsaturated group polymerizable with radicals, and the copolymer of a (meth)acrylic ester has a weight-average molecular weight of 100,000 or greater.

10. A sheet for circuit substrates according to claim 1, wherein the polymer material of an energy ray hardening type comprises a photoinitiator.

11. A sheet for circuit substrates according to claim 3, wherein the polymer material of an energy ray hardening type comprises a photoinitiator.

12. A sheet of a circuit substrate for displays obtained by embedding circuit chips into an unhardened layer comprising a polymer material of an energy ray hardening type in a sheet for circuit substrates described in claim 1, followed by hardening the unhardened layer by irradiation with an energy ray.

13. A sheet of a circuit substrate for displays obtained by embedding circuit chips into an unhardened layer comprising a polymer material of an energy ray hardening type in a sheet for circuit substrates described in claim 3, followed by hardening the unhardened layer by irradiation with an energy ray.
